(19) United States
(12) Patent Application Publication
(10) Pub. No.: US 2025/0364616 A1
(43) Pub. Date: Nov. 27, 2025

(54) BATTERY CELL WITH ION SENSOR FOR THERMAL RUNAWAY DETECTION

(71) Applicant: GM GLOBAL TECHNOLOGY OPERATIONS LLC., Detroit, MI (US)

(72) Inventors: Ziliang ZHENG, Auburn Hills, MI (US); Ryan Patrick HICKEY, Austin, TX (US); Jeremie DERNOTTE, Canton, MI (US); Peter Paul ANDRUSKIEWICZ, IV, Ann Arbor, MI (US)

(21) Appl. No.: 18/670,076

(22) Filed: May 21, 2024

(51) Int. Cl. H01M 10/48; H01M 10/42; H01M 50/148; H01M 50/15; H01M 50/176; H01M 50/209; H01M 50/258; H01M 50/342

(52) U.S. Cl. CPC H01M 10/482; H01M 10/4257; H01M 50/154; H01M 50/258; H01M 50/3425; H01M 50/15; H01M 50/176; H01M 50/209

(57) ABSTRACT

A thermal runaway detection system for a battery cell includes a battery cell enclosure including a lid portion and a bottom portion. A battery electrode stack is arranged in the battery cell enclosure and includes anode electrodes, cathode electrodes, and separators. An ion sensor arranged in the battery cell enclosure and including a first electrode and a second electrode configured to detect ions in gas passing there between.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells, and more particularly to battery cells with an ion sensor for detecting thermal runaway.

Electric vehicles (EVs) such as battery electric vehicles (BEVs), hybrid vehicles, and/or fuel cell vehicles include one or more electric machines and a battery system including one or more battery cells connected in one or more battery modules and/or battery packs. A power control system is used to control charging and/or discharging of the battery system during charging and/or driving.

Battery cells include one or more cathode electrodes, anode electrodes, and separators. The cathode electrodes include a cathode active material layer arranged on a cathode current collector. The anode electrodes include an anode active material layer arranged on an anode current collector. When one or more of the battery cells have a fault, the battery produces additional gases and/or the temperature of the battery cell may increase. The increased temperature of one battery cell may also cause other battery cells to fail and a thermal runaway (TR) process may propagate unless mitigating action is taken.

### SUMMARY

A thermal runaway detection system for a battery cell includes a battery cell enclosure including a lid portion and a bottom portion. A battery electrode stack is arranged in the battery cell enclosure and includes anode electrodes, cathode electrodes, and separators. An ion sensor arranged in the battery cell enclosure and including a first electrode and a second electrode configured to detect ions in gas passing there between.

In other features, a membrane is arranged on one side of the ion sensor. An insulator plate is arranged between the battery electrode stack and the lid portion. The ion sensor is mounted on the insulator plate.

In other features, a gas vent is arranged on the lid portion, wherein the ion sensor is arranged adjacent to the gas vent.

In other features, a cradle is arranged between the battery electrode stack and the lid portion. The ion sensor is mounted between the cradle and the lid portion.

In other features, first current collectors are connected to the anode electrodes, and second current collectors connected to the cathode electrodes. The ion sensor is arranged between the first current collectors and the second current collectors.

In other features, the lid portion includes a bore and a seal. A conductor passes through the bore and the seal and is connected to the ion sensor. A controller is connected to the conductor and is configured to detect thermal runaway in response to the ion sensor.

A flex circuit comprises a flexible substrate that is made of a nonconducting material. A plurality of conductive traces are arranged in a predetermined pattern on the flexible substrate. An ion sensor includes a first electrode and a second electrode arranged on the flexible substrate.

A system comprises the flex circuit and a battery module including a plurality of battery cells. The ion sensor of the flex circuit is arranged adjacent to a vent of at least one of the plurality of battery cells.

In other features, the plurality of battery cells includes B of the battery cells, where B is an integer greater than one, and the flex circuit includes B of the ion sensors arranged adjacent to the B battery cells, respectively.

A system comprises the flex circuit and a battery pack including a plurality of battery modules. The ion sensor of the flex circuit is arranged adjacent to a vent of at least one of the plurality of battery modules.

In other features, the plurality of battery modules includes M of the battery modules, where M is an integer greater than one. The flex circuit includes M of the ion sensors arranged adjacent to the M battery modules, respectively.

A thermal runaway detection system for a battery cell includes an enclosure including a lid portion and a bottom portion. A battery electrode stack is arranged in the enclosure and includes anode electrodes, cathode electrodes, and separators. A sensor includes a first electrode and a second electrode passing through the lid portion. The first electrode and the second electrode are configured to detect ions in gas passing there between.

In other features, an insulator plate is arranged between the battery electrode stack and the lid portion. The first electrode and the second electrode pass through the insulator plate.

In other features, when ends of the first electrode and the second electrode are in contact with electrolyte, the sensor is used to detect electrolyte presence. When ends of the first electrode and the second electrode are not in contact with electrolyte, the sensor is used to detect ions in gas in the enclosure. A controller is connected to the first electrode and the second electrode and is configured to detect thermal runaway in response to the sensor.

In other features, a controller connected to the first electrode and the second electrode and configured to detect a parameter of electrolyte in the enclosure in response to the sensor when ends of the first electrode and the second electrode are immersed in the electrolyte, and detect thermal runaway in response to the sensor when the ends of the first electrode and the second electrode are not immersed in electrolyte. The parameter is selected from a group consisting of electrolyte presence and half-cell voltage.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a battery cell including a battery electrode stack including anode electrodes, cathode electrodes, and separators arranged in a battery enclosure;

FIG. 2 is a perspective view of an example of the battery enclosure including a battery electrode stack and an ion sensor mounted on an insulator plate between the battery electrode stack and a cover of the enclosure according to the present disclosure;

FIG. 3 is a side view of an example of an ion sensor mounted on an insulator plate between the battery electrode stack and the lid portion according to the present disclosure;

FIG. 4 is a perspective view of another example of ion sensor mounted between the cradle and a lid portion in the battery enclosure according to the present disclosure;

FIG. 5 is an enlarged side view of an example of another ion sensor according to the present disclosure;

FIG. 6 is a functional block diagram of an example of an ion sensor including electrodes passing through a cover of a battery enclosure according to the present disclosure;

FIG. 7 is a functional block diagram of an example of a sensor for monitoring electrolyte presence and sensing ions in gas and mounted through a cover of a battery enclosure according to the present disclosure;

FIG. 8 is a flowchart of an example of a method for operating the sensor of FIG. 7 according to the present disclosure;

FIG. 9 is a functional block diagram of an example of a battery module including a plurality of battery cells and a battery monitoring circuit connected to a flex circuit with an ion sensor according to the present disclosure;

FIG. 10 is a plan view of an example of a flex circuit including an ion sensor according to the present disclosure;

FIG. 11A is a functional block diagram of an example of a battery pack including a plurality of battery modules and a battery monitoring circuit connected to a flex circuit with an ion sensor according to the present disclosure; and

FIG. 11B is a functional block diagram of an example of a battery pack including a plurality of battery modules and a battery monitoring circuit connected to an ion sensor arranged inside of the battery module or battery pack according to the present disclosure.

In the drawings, reference numbers may be reused to identify similar and/or identical elements.

### DETAILED DESCRIPTION

While the present disclosure describes a battery cell including an ion sensor for a vehicle, the battery cells can be used in other vehicles or stationary applications.

An ion sensor according to the present disclosure enhances sensing capabilities of battery cells, modules, and/or packs in a rechargeable energy storage system (RESS) while reducing hardware cost and thermal runaway propagation (TRP) risk. The ion sensors eliminate some of the issues of delayed TRP gas detection that are caused by transport delay and diffusion processes, which can diminish the effectiveness of TRP mitigation.

In some examples, the ion sensor is arranged inside of the battery cell enclosure to detect the onset of thermal runaway propagation as early as possible. Prompt detection of thermal runaway gases allow for timely actions to mitigate safety risks and/or provide early warnings. Additionally, the use of the ion sensors as described further below reduces reliance on thermocouples and/or gas detectors in the battery module and/or pack, which lowers cost.

In addition, the ion sensor detects changes in the gas during the lifespan of the battery cell, module, or pack. The stored data from the ion sensors can be used to support battery aging algorithms. For example, the ion sensor may exhibit an increasing signal level over the operating life of the battery cell, module, or pack. When the signal level generated by the ion sensor spikes, corrective action may be initiated earlier than other control approaches that occur after the vent cap of the battery cell bursts.

In other words, sensors that are used to detect thermal runaway are usually installed outside of the battery cell in the module or pack, which causes detection delays. In some examples, the ion sensor is arranged in the battery cell enclosure, battery module, and/or battery pack. Locating the ion sensor in the battery cell enables immediate detection of thermal runaway gases to provide earlier warnings and/or time for mitigation to be performed. Locating the ion sensor in the battery module or battery pack enables detection of vent gases during thermal runaway.

In some examples, the ion sensor can be implemented in flex circuits that are used to provide connections to sensors outside of battery modules and/or battery packs to sense vent gases during a thermal runaway event. Locating the ion sensors on the flex circuits reduces cost (with a corresponding delay until gases burst the vent and reach the ion sensor). In some examples, a sensor is initially used to detect electrolyte decomposition. The sensor senses the present of electrolyte when wet. When the electrolyte level falls below distal ends of the electrodes, the sensor monitors ions in the gas in the battery cell.

Unlike prior designs that are limited to aging models based on parallel grouping of battery cells, the ion sensor enables individual cell aging prediction within the same parallel group. The use of this monitoring approach will enhance understanding of cell-to-cell aging and allow optimization of battery performance.

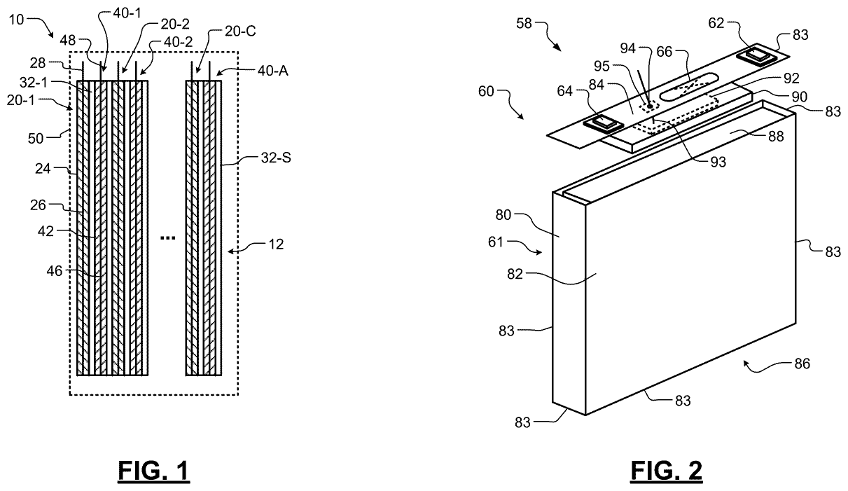

Referring now to FIG. 1, a battery cell 10 includes C cathode electrodes 20, A anode electrodes 40, and S separators 32-1, 32-2, . . . , and 32-S arranged in a predetermined sequence in a battery electrode stack 12, where C, S and A are integers greater than zero. The C cathode electrodes 20-1, 20-2, . . . , and 20-C include cathode active material layers 24 arranged on one or both sides of a cathode current collector 26.

In some examples, the A anode electrodes 40 and the C cathode electrodes 20 exchange lithium ions during charging/discharging. The A anode electrodes 40-1, 40-2, . . . , and 40-A include anode active material layers 42 arranged on one or both sides of the anode current collectors 46. In some examples, the cathode active material layers 24 and/or the anode active material layers 42 comprise coatings including one or more active materials, one or more conductive additives, and/or one or more binder materials that are applied to the current collectors (e.g., using a wet or dry roll-to-roll process).

In some examples, the cathode current collector 26 and/or the anode current collector 46 comprises metal foil, metal mesh, perforated metal, 3 dimensional (3D) metal foam, and/or expanded metal. In some examples, the current collectors are made of one or more materials selected from a group consisting of copper, stainless steel, brass, bronze, zinc, aluminum, and/or alloys thereof. External tabs 28 and 48 are connected to the current collectors of the cathode electrodes and anode electrodes, respectively, and can be arranged on the same or different sides of the battery electrode stack 12. The external tabs 28 and 48 are connected to terminals of the battery cells.

Referring now to FIG. 2, a battery cell 58 includes an enclosure 60. In some examples, the enclosure 60 has a prismatic shape with rectangular cross-sections in x-, y- and z-axis planes, although other types of enclosures may be used. In some examples, the enclosure 60 includes an enclosure body 61 including sides 80 corresponding to narrow faces and sides 82 corresponding to wide faces. The enclosure body 61 defines an open-ended rectangular prism. In some examples, the enclosure 60 includes a lid portion 84 and a bottom portion 86. In other examples, the bottom portion 86 is attached after the enclosure 60 is formed. Edges 83 are arranged between the sides 80 and 82, the sides 80 and 82 and a lid portion 84, the sides 80 and 82 and the bottom portion 86.

The lid portion 84 and optionally the bottom portion 86 are attached to the enclosure body 61 to enclose top and the bottom openings of the enclosure body 61, respectively. The battery cell 58 includes external terminals 62 and 64 that pass through the lid portion 84. The battery electrode stack 12 includes the C cathode electrodes 20, the A anode electrodes 40, and the S separators 32 is arranged in the enclosure 60.

The external terminals 62 and 64 are connected to external tabs 28 and 48 of the C cathode electrodes 20 and the A anode electrodes 40, respectively. The lid portion 84 (and/or the bottom portion 86) includes a vent cap 66. The vent cap 66 is configured to release vent gases when pressure within the inner enclosure is greater than a predetermined pressure.

A battery electrode stack 88 is arranged inside of the enclosure 60. An insulator plate 90 is arranged between the battery electrode stack 88 and the lid portion 84. An ion sensor 92 is mounted on the insulator plate 90 inside of the enclosure 60. In some examples, the ion sensor 92 is arranged below the vent cap 66. The ion sensor 92 is connected by conductors 93 through a bore 94 in the lid portion 84. A seal 95 may be used to seal around the conductors 93 and the bore 94.

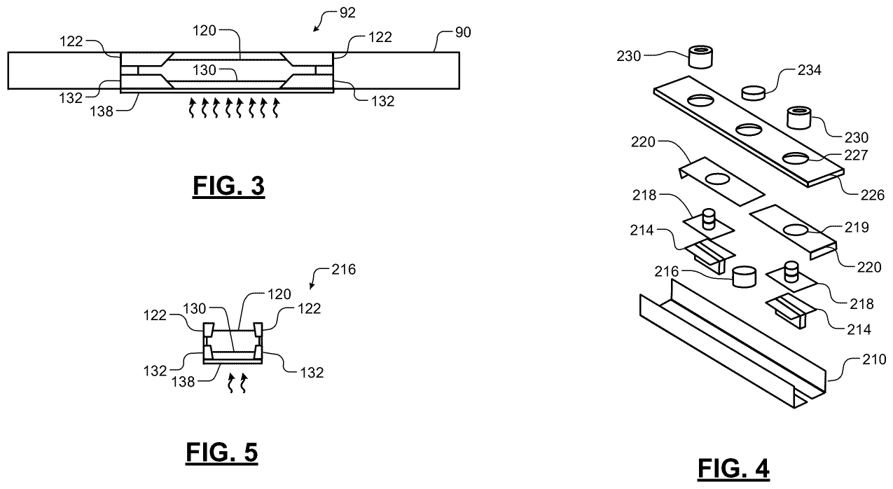

Referring now to FIG. 3, the ion sensor 92 is shown mounted on the insulator plate 90. The ion sensor 92 includes a first electrode 120 extending between mounts 122 and a second electrode 130 extending between mounts 132. Locations of the mounts 122 and 132 define a hole and predetermined horizontal and vertical gaps (defining a flow area) between the first electrode 120 and the second electrode 130.

A membrane 138 may be arranged on one side of the ion sensor 92 to prevent false detection from electrolyte splashing or gas generation during normal operation. When ions are generated, the membrane 138 allows gas to flow across a gap between the first electrode 120 and the second electrode. Gas flows though the membrane 138 and across the first electrode 120 and the second electrode 130. In some examples, the first electrode 120 is grounded and the second electrode 130 is a sensing electrode. Parameters such as voltage, current, resistance, capacitance, etc. can be detected between the first electrode 120 and the second electrode 130. In other examples, the second electrode 130 is grounded and the first electrode 120 is a sensing electrode. A flow area and hole size of the ion sensor 92 can be optimized to accommodate different battery cell sizes.

In some examples, the ion sensor 92 is configured to sense molecular hydrogen (H₂) gas. In some examples, the ion sensor 92 detects electrons generated when hydrogen ions (H⁺) are created. Light molecular weight species (e.g., molecular hydrogen H₂) produce more electrons than other heavier molecular weight species. The electrons that are generated when hydrogen ions (H⁺) are created creates detectable signa (e.g., a strong signal with a sufficient amplitude).

Referring now to FIGS. 4 and 5, another example location for the ion sensor is shown. A cradle 210 is mounted in a battery enclosure above the battery electrode stack (for example as shown in FIG. 2). Current collectors 214 (e.g., anode and cathode current collectors) are connected to terminals 218 (e.g., positive and negative terminals). The terminals 218 extend through bores 219 in holding plates 220 and a lid portion 226 including bores 227. In some examples, washers 230 are arranged around the terminals 218. A vent 234 is arranged in one of the bores 227 on the lid portion 226.

An ion sensor 216 is arranged between the cradle 210 and the lid portion 226 below the vent 234. In some examples, the ion sensor 216 is arranged between the current collectors 214. In FIG. 5, the ion sensor 216 can have a smaller form factor and hole as compared to the ion sensor in FIG. 3.

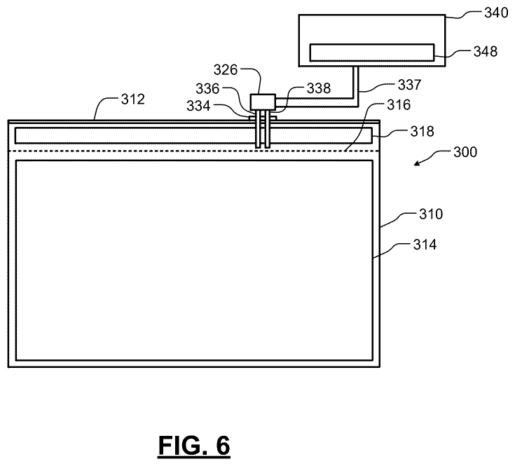

Referring now to FIG. 6, a battery cell 300 includes an enclosure 310 including a lid portion 312. An ion sensor 313 includes electrodes 336 and 338 that extend through the lid portion 312 and/or an insulator plate 318 of the enclosure 310. A seal 334 may be used to contain gas. In this example, ends of the electrodes 336 and 338 are located above the electrolyte 316. The sensor 326 monitor ions in the gas in the enclosure 310 to allow thermal runaway to be detected. Conductors 337 connect the electrodes 336 and 338 to a controller 340. The controller 340 includes a thermal runaway (TR) detector 348 that detects changes in the sensed ions in the gas and selectively detects TR based thereon.

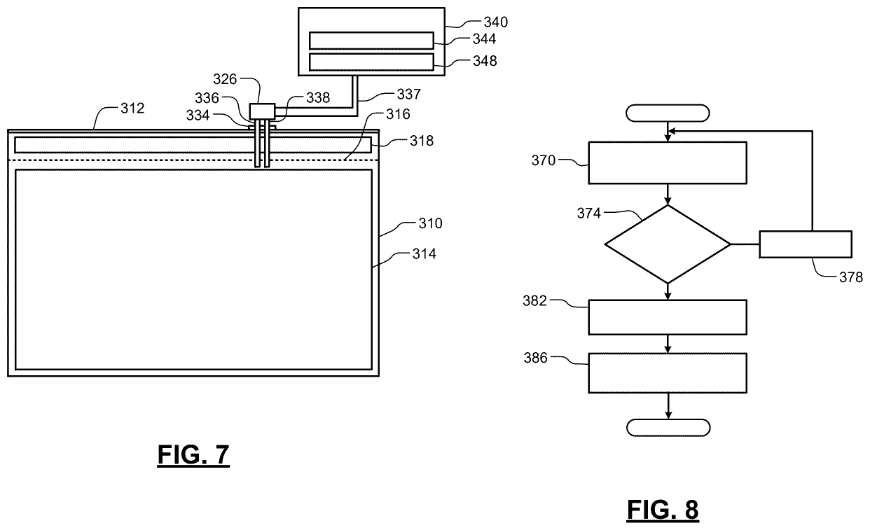

Referring now to FIGS. 7 and 8, a sensor 326 includes the electrodes 336 and 338 that extend through the lid portion 312 and/or the insulator plate 318 of the enclosure 310. The electrodes 336 and 338 are initially used to monitor a parameter of electrolyte 316 in the enclosure 310 (e.g., present of electrolyte). In this example, ends of the electrodes 336 and 338 are initially located in the electrolyte 316.

In some examples, one of the electrodes 336 and 338 is coated with a cathode material (e.g., lithium iron phosphate (LFP) or an anode material (e.g., plated Li metal). When configured in this way, the electrodes 336 and 339 produce a half-cell voltage. The controller uses the half-cell voltage along with other parameters to determine battery state of health (SOH). Alternately, the electrodes 336 and 338 can be used to monitor one or more cell parameters to set lithium plating limits during charging at various different temperatures.

As the battery cell ages, the electrolyte decomposes. If the level of the electrolyte 316 falls below lower ends of the electrodes 336 and 338 of the sensor 326, the function of the sensor 326 is adjusted.

The sensor 326 monitor ions in gas in the enclosure 310 to detect TR. The conductors 337 that are connected to the electrodes 336 and 338 connect the ion sensor to a controller 340. The controller 340 includes an electrolyte detector 344 and a TR detector 348. The electrolyte detector 344 detects the presence of the electrolyte 316 until the electrolyte level falls below distal ends of the electrodes 336 and 338. Then, the electrodes 336 and 338 are used to detect ions in the enclosure 310. The controller 340 selectively detects thermal runaway based on the sensed ion levels in the gas.

In FIG. 8, a method for operating the sensor of FIG. 7 is shown. At 370, the sensor generates signals based on the electrolyte in the battery enclosure and the controller determines whether the electrolyte is present based on the sensed parameter(s). When the electrolyte is above distal ends of the electrodes as determined at 374, electrolyte presence is determined and reported at 378. In some examples, the sensor acts as an immersion-type sensor that senses whether the distal ends of the electrodes of the sensor are wetted by the electrolyte (e.g., with a path to ground (high enough), or not submerged (low)).

When the electrolyte level falls below distal ends of the electrodes of the sensor as determined at 374, the controller generates an electrolyte fault at 382. The controller switches operation of the sensor to ion detection at 386. The controller detects TR in response to the sensed ions in the gas.

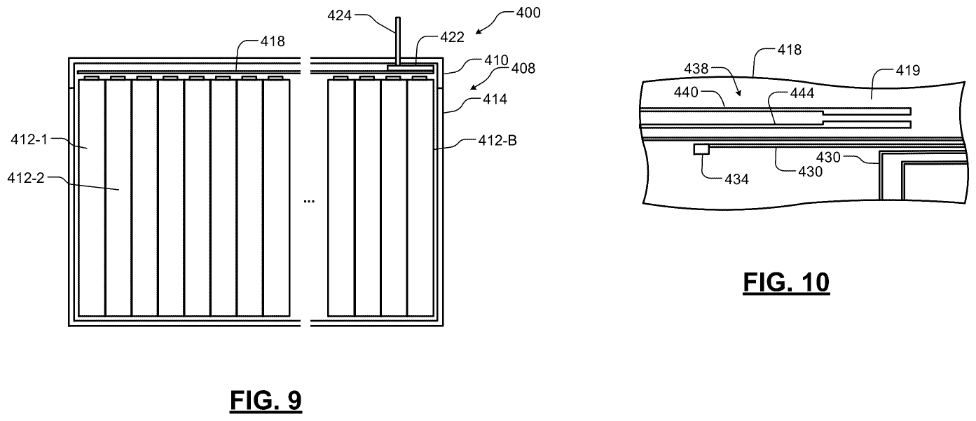

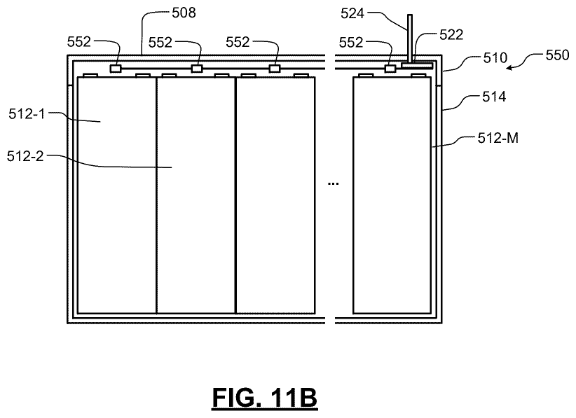

Referring now to FIGS. 9 to 11, the ion sensors can also be used in battery modules (FIG. 9) or battery packs (FIG. 11). In FIG. 9, a battery module 400 includes an enclosure 408 (e.g., including a lid portion 410 and a bottom portion 414). The battery module 400 includes a plurality of battery cells 412-1, 412-2, . . . , and 412-B (where B is an integer) arranged in the enclosure 408. The battery module 400 may include a battery monitoring circuit 422 arranged inside of the enclosure 408 (or the battery monitoring circuit 422 can be located outside of enclosure 408). The battery monitoring circuit 422 can be connected by a conductor 424 extending through the enclosure 408.

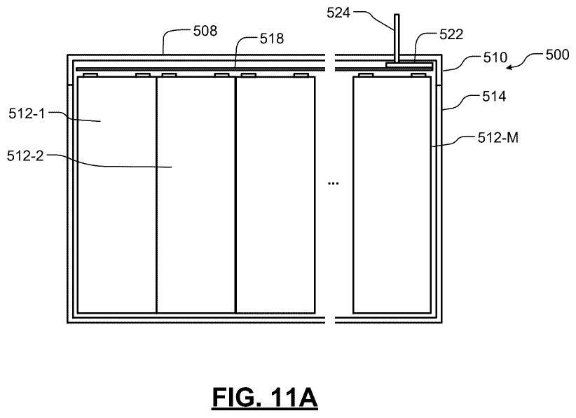

Connections to the battery cells 412-1, 412-2, . . . , and 412-B and/or various sensors are made using a flex circuit 418 arranged above the battery cells. In FIG. 10, the flex circuit 418 includes a flexible substrate 419 (such as a polymer substrate) and conductive traces 430 arranged in a predetermined pattern on the flexible substrate 419. The conductive traces 430 on the flex circuit 418 are used to make connections to the battery cells 412-1, 412-2, . . . , and 412-B and/or sensors 434 for sensing voltage, current, pressure, and/or other parameters. The flex circuit 418 further includes an ion sensor 438 including a first electrode 440 and a second electrode 444. Since the flex circuit 418 is arranged over multiple battery cells, the flex circuit 418 can include more than one of the ion sensor 438. In some examples, multiple ion sensors 438 are arranged in the enclosure 408 over the vents of each of the battery cells 412-1, 412-2, . . . , and 412-B. In other examples, a single ion sensor 438 is used in the enclosure 408 or multiple ion sensors 438 are arranged over some but not all of the vents of the battery cells 412-1, 412-2, . . . , and 412-B.

In FIG. 11A, a battery pack 500 includes an enclosure 508 (e.g., including a lid portion 510 and a bottom portion 514). The battery pack 500 includes a plurality of battery modules 512-1, 512-2, . . . , and 512-M (where M is an integer) arranged in the enclosure 508. The battery pack 500 may include a battery monitoring circuit 522 arranged inside of the enclosure 508 and connected externally by conductor(s) 524 (or the battery monitoring circuit 522 can be located outside of enclosure 508). If the battery monitoring circuit 522 is arranged in the enclosure 508. Connections to the battery modules 512-1, 512-2, . . . , and 512-B are made using a flex circuit 518 that is similar to the flex circuit 418 described above. The flex circuit includes one or more ion sensors 438 as shown in FIG. 10.

In FIG. 11B, battery pack 550 includes one or more ion sensors 552 that are arranged within the enclosure 508.

The ion sensor design ensures reliable early warnings for thermal runaway propagation (TRP) by detecting gas venting inside the battery cell during such events. When the ion sensor is located inside of the enclosure, the ion sensor allows the controller to detect the location of TR onset. Using signals generated by the ion sensors in the battery cells allows a propagation rate of thermal runaway to be determined, which is beneficial for developing accurate notification strategies and enhancing safety measures.

The ion sensor described herein may also eliminate or reduce the reliance on pressure sensors, thermocouples, and/or gas detectors for TRP detection purposes in the battery module and pack, which simplifies the design. The ion sensor can be utilized to detect cell aging by monitoring electrolyte decomposition and gas generation during normal battery operation. The ion sensor enables individual cell aging prediction within the same parallel group that optimizes battery performance through the lifespan of the battery. The ion sensor can be used to detect manufacturing defects during the initial formation cycle of the battery cell.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®

What is claimed is:

1. A thermal runaway detection system for a battery cell, comprising:
a battery cell enclosure including a lid portion and a bottom portion;
a battery electrode stack arranged in the battery cell enclosure and including anode electrodes, cathode electrodes, and separators; and
an ion sensor arranged in the battery cell enclosure and including a first electrode and a second electrode configured to detect ions in gas passing there between.

2. The thermal runaway detection system of claim 1, further comprising a membrane arranged on one side of the ion sensor.

3. The thermal runaway detection system of claim 1, further comprising an insulator plate arranged between the battery electrode stack and the lid portion, wherein the ion sensor is mounted on the insulator plate.

4. The thermal runaway detection system of claim 3, further comprising a gas vent arranged on the lid portion, wherein the ion sensor is arranged adjacent to the gas vent.

5. The thermal runaway detection system of claim 1, further comprising a cradle arranged between the battery electrode stack and the lid portion, wherein the ion sensor is mounted between the cradle and the lid portion.

6. The thermal runaway detection system of claim 5, further comprising:
first current collectors connected to the anode electrodes; and
second current collectors connected to the cathode electrodes,
wherein the ion sensor is arranged between the first current collectors and the second current collectors.

7. The thermal runaway detection system of claim 1, wherein:
the lid portion includes a bore and a seal; and
a conductor passes through the bore and the seal and is connected to the ion sensor.

8. The thermal runaway detection system of claim 7, further comprising a controller connected to the conductor and configured to detect thermal runaway in response to the ion sensor.

9. A flex circuit comprising:
a flexible substrate that is made of a nonconducting material;
a plurality of conductive traces arranged in a predetermined pattern on the flexible substrate; and
an ion sensor including a first electrode and a second electrode arranged on the flexible substrate.

10. A system comprising:
the flex circuit of claim 9; and
a battery module including a plurality of battery cells,
wherein the ion sensor of the flex circuit is arranged adjacent to a vent of at least one of the plurality of battery cells.

11. The system of claim 10, wherein:
the plurality of battery cells includes B of the battery cells, where B is an integer greater than one, and
the flex circuit includes B of the ion sensors arranged adjacent to the B battery cells, respectively.

12. A system comprising:
the flex circuit of claim 9; and
a battery pack including a plurality of battery modules,
wherein the ion sensor of the flex circuit is arranged adjacent to a vent of at least one of the plurality of battery modules.

13. The system of claim 12, wherein:
the plurality of battery modules includes M of the battery modules, where M is an integer greater than one, and
the flex circuit includes M of the ion sensors arranged adjacent to the M battery modules, respectively.

14. A thermal runaway detection system for a battery cell, comprising:
an enclosure including a lid portion and a bottom portion;
a battery electrode stack arranged in the enclosure and including anode electrodes, cathode electrodes, and separators; and
a sensor including a first electrode and a second electrode passing through the lid portion,
wherein the first electrode and the second electrode are configured to detect ions in gas passing there between.

15. The thermal runaway detection system of claim 14, further comprising an insulator plate arranged between the battery electrode stack and the lid portion, wherein the first electrode and the second electrode pass through the insulator plate.

16. The thermal runaway detection system of claim 14, wherein when ends of the first electrode and the second electrode are in contact with electrolyte, the sensor is used to detect a parameter of the electrolyte.

17. The thermal runaway detection system of claim 14, wherein when ends of the first electrode and the second electrode are not in contact with electrolyte, the sensor is used to detect ions in gas in the enclosure.

18. The thermal runaway detection system of claim 14, further comprising a controller connected to the first electrode and the second electrode and configured to detect thermal runaway in response to the sensor.

19. The thermal runaway detection system of claim 14, further comprising a controller connected to the first electrode and the second electrode and configured to:
detect a parameter of electrolyte in the enclosure in response to the sensor when ends of the first electrode and the second electrode are immersed in the electrolyte; and
detect thermal runaway in response to the sensor when the ends of the first electrode and the second electrode are not immersed in electrolyte.

20. The thermal runaway detection system of claim 19, wherein the parameter is selected from a group consisting of electrolyte presence and half-cell voltage.
